(19) United States
(12) Patent Application Publication
(10) Pub. No.: US 2025/0350193 A1
(43) Pub. Date: Nov. 13, 2025

(54) CONTROLLER, POWER FACTOR CORRECTION CIRCUIT, ELECTRONIC DEVICE, AND OFFSET SETTING METHOD

(71) Applicant: ROHM CO., LTD., Kyoto (JP)

(72) Inventors: Manae ITO, Kyoto (JP); Satoshi MAEJIMA, Kyoto (JP)

(21) Appl. No.: 19/197,216

(22) Filed: May 2, 2025

(30) Foreign Application Priority Data
May 10, 2024 (JP) 2024-077039

(51) Int. Cl. H02M 1/42; G01R 1/20; H02M 1/00

(52) U.S. Cl. CPC H02M 1/4208; G01R 1/203; H02M 1/0025

(57) ABSTRACT

A controller configured to control a power factor correction (PFC) circuit including a DC/DC converter, includes: a first external terminal receiving a full-wave rectified first voltage; a second external terminal receiving a first detection voltage generated by a current flowing through a sense resistor connected to a ground potential; an error amplifier circuit generating a second voltage by amplifying an error between a second detection voltage corresponding to the DC/DC converter's output voltage and a reference voltage; an arithmetic circuit generating a third voltage by multiplying the first and second voltages; an inverting amplifier generating a fourth voltage from the first detection voltage; a comparator comparing the third and fourth voltages; and a drive circuit driving a switching element in the PFC circuit to be turned on or off such that the switching element is turned off each time the fourth voltage becomes higher than the third voltage.

### CROSS-REFERENCE TO RELATED APPLICATION

The present invention claims priority under 35 U.S.C. § 119 to Japanese Patent Application No. 2024-077039, filed on May 10, 2024, the entire contents of which are incorporated herein by reference.

### TECHNICAL FIELD

The present disclosure relates to a controller.

### BACKGROUND

In the related art, a power factor correction circuit brings the power factor close to 1 (i.e., 100%) by aligning a phase of an AC input voltage and a phase of an AC input current.

### BRIEF DESCRIPTION OF DRAWINGS

The accompanying drawings, which are incorporated in and constitute a part of the specification, illustrate embodiments of the present disclosure.

FIG. 1 is a circuit diagram showing an example of a configuration of an electronic device.

FIG. 2 is a circuit diagram showing a configuration of a PFC circuit according to a first comparative example.

FIG. 3 is a diagram showing an example of an offset voltage generation circuit.

FIG. 4 is a diagram showing an example of a first arithmetic circuit.

FIG. 5 is a diagram showing an example of a first conversion circuit.

FIG. 6 is a diagram showing an example of a second conversion circuit.

FIG. 7 is a diagram showing an example of a second arithmetic circuit.

FIG. 8 is a diagram showing an example of waveforms of an AC voltage and an input current.

FIG. 9 is a diagram showing a configuration of a PFC circuit according to a second comparative example.

FIG. 10 is a timing chart showing an example of an operation of the PFC circuit according to the second comparative example.

FIG. 11 is a diagram showing a configuration of a PFC circuit according to an embodiment of the present disclosure.

FIG. 12 is a timing chart showing an example of an operation of the PFC circuit according to an embodiment of the present disclosure.

FIG. 13 is a diagram for explaining an offset difference ΔV.

FIG. 14 is a diagram showing a specific example of configurations of an arithmetic circuit and an inverting amplifier.

FIG. 15 is a diagram showing a configuration related to a step of setting an offset difference ΔV.

FIG. 16 is a timing chart showing an exemplary measurement of an offset voltage V5_offset.

FIG. 17 is a diagram showing a configuration for measurement of an offset voltage Voffset.

FIG. 18 is a diagram showing a specific example of a configuration of an offset generator.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, exemplary embodiments of the present disclosure will be described with reference to the drawings.

### Electronic Device

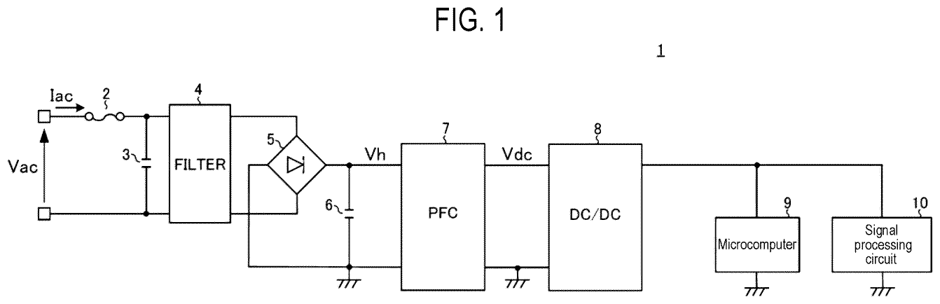

FIG. 1 is a circuit diagram showing an exemplary configuration of an electronic device. Examples of the electronic device 1 shown in FIG. 1 may include home appliances such as televisions, refrigerators, and air conditioners, computers, or the like. The electronic device 1 includes a fuse 2, a capacitor 3, a filter 4, a rectifier circuit 5, a capacitor 6, and a power factor correction (PFC) circuit 7. The electronic device 1 further includes a DC/DC converter 8, a microcomputer 9, and a signal processing circuit 10. The electronic device 1 is divided into a primary side and a secondary side, which are insulated from each other, with an insulated transformer (not shown) of the DC/DC converter 8 as a boundary.

The rectifier circuit 5 is, for example, a diode bridge. An AC voltage Vac such as a commercial AC voltage is supplied to the rectifier circuit 5 via the fuse 2, the capacitor 3, and the filter 4. The rectifier circuit 5 generates a first voltage Vh by full-wave rectifying the AC voltage Vac. Therefore, the first voltage Vh has a full-wave rectified waveform.

The first voltage Vh is supplied to the PFC circuit 7 via the capacitor 6. The PFC circuit 7 includes a step-up type DC/DC converter (switching regulator) configured to generate an output voltage Vdc from the first voltage Vh. The PFC circuit 7 improves a power factor by approximately matching a phase of the first voltage Vh with a phase of an input current Iac.

The DC/DC converter 8 receives the output voltage Vdc of the PFC circuit 7, steps down the output voltage Vdc thus received, and supplies the same to the microcomputer 9 and the signal processing circuit 10 respectively, which serve as loads.

The microcomputer 9 controls the entire electronic device 1 in an integrated manner. The signal processing circuit 10 is a block configured to perform specific signal processing, and examples of such a circuit may include an interface circuit configured to communicate with external devices, an image processing circuit, an audio processing circuit, and the like. In the actual electronic device 1, it goes without saying that a plurality of signal processing circuits 10 are provided depending on the function.

The above is a description of the configuration of the electronic device 1. In this way, AC/DC conversion is performed by the electronic device including the rectifier circuit 5 configured to full-wave rectify the AC voltage Vac, and the PFC circuit 7 configured to step up the full-wave rectified first voltage Vh to generate the output voltage Vdc. Next, details of the PFC circuit 7 mounted on the electronic device 1 will be described. Note that, for the sake of convenience, in comparative examples to be described below, the reference number “7” of the PFC circuit will be affixed with “A” or “B.”

### FIRST COMPARATIVE EXAMPLE

### PFC Circuit (Positive Voltage Control Type)

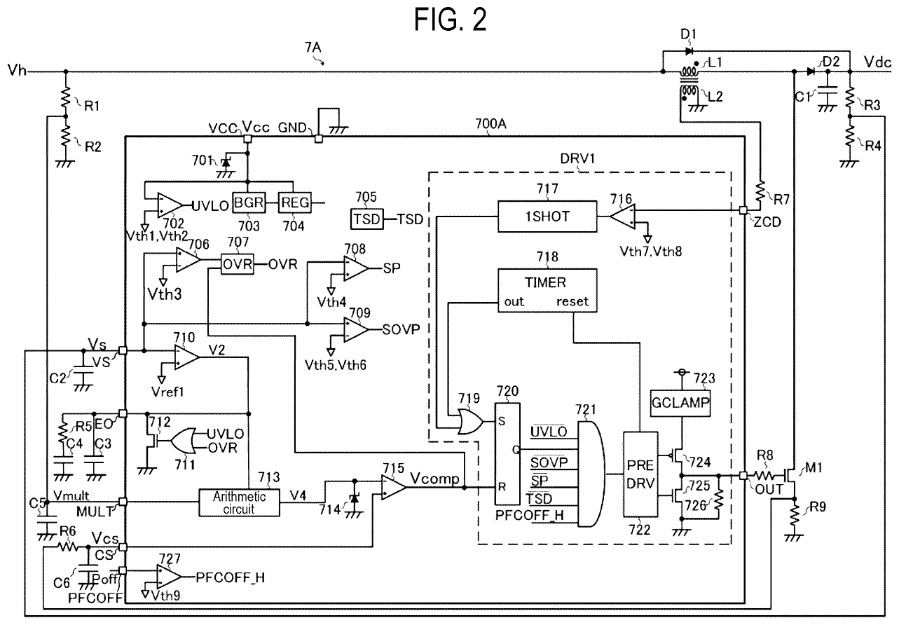

Prior to describing an embodiment of the present disclosure, comparative examples will be described for comparison. This will make a problem to be solved more obvious. FIG. 2 is a circuit diagram showing a configuration of a PFC circuit 7A according to a first comparative example. As described above, the PFC circuit 7A includes a step-up type DC/DC converter (switching regulator). Unlike this embodiment, the PFC circuit 7A may include a DC/DC converter other than the step-up type DC/DC converter. The PFC circuit 7A having the configuration shown in FIG. 2 is a positive voltage control type PFC circuit, as will be described later.

The PFC circuit 7A includes a controller 700A, resistors R1 to R9, capacitors C1 to C6, diodes D1 and D2, inductors L1 and L2, and a switching transistor M1. In the present embodiment, the switching transistor M1 is an NMOS transistor (N-channel MOSFET (Metal-Oxide-Semiconductor Field-Effect Transistor)). Note that, although the switching transistor is provided outside the controller in the configuration shown in FIG. 2, without being limited thereto, the switching transistor may be built into the controller.

The controller 700A is a device configured to control the PFC circuit 7A, and includes an IC that integrates the internal configuration shown in FIG. 2. The controller 700A includes terminals VCC, GND, ZCD, OUT, CS, MULT, EO, and VS as external terminals configured to establish electrical connections with the outside.

A first voltage Vh is applied to one end of the resistor R1. The other end of the resistor R1 is connected to one end of the resistor R2, one end of the capacitor C5, and a terminal MULT. The other end of the resistor R2 and the other end of the capacitor C5 are connected to a ground terminal (an application terminal of the ground potential). According to this configuration, a voltage Vmult, which is a voltage obtained by dividing the first voltage Vh by the resistors R1 and R2, is supplied to the terminal MULT.

The one end of the resistor R1 is connected to one end of an inductor L1 and an anode of a diode D1. The other end of the inductor L1 is connected to an anode of a diode D2 and a drain of the switching transistor M1. Each of cathodes of the diodes D1 and D2 is connected to one end of a capacitor C1. The other end of the capacitor C1 is connected to the ground terminal, a gate of the switching transistor M1 is connected to a terminal OUT via a resistor R8, and a source of the switching transistor M1 is connected to the ground terminal via a resistor R9. According to this configuration, the PFC circuit 7A is provided with a step-up type DC/DC converter (switching regulator). A voltage Vdc, which is an output voltage of the step-up type DC/DC converter (switching regulator), is output from the one end of the capacitor C1.

The inductors L1 and L2 are magnetically coupled. One end of the inductor L2 is connected to a terminal ZCD via the resistor R7. The other end of the inductor L2 is connected to the ground terminal. According to this configuration, the controller 700A can detect zero crossing of a current flowing through the inductor L1 by monitoring a voltage supplied to the terminal ZCD.

The output voltage Vdc is applied to one end of the resistor R3. The other end of the resistor R3 is connected to one end of the resistor R4, one end of the capacitor C2, and the terminal VS. The other end of the resistor R4 and the other end of the capacitor C2 are connected to the ground terminal. According to this configuration, a detection voltage Vs, which is a voltage obtained by dividing the output voltage Vdc by the resistors R3 and R4, is supplied to the terminal VS.

One end of the resistor R9 is connected to the source of the switching transistor M1, and the other end of the resistor R9 is connected to the ground terminal. A voltage proportional to a current flowing through the switching transistor M1 (a drain current of the switching transistor M1) is generated across the resistor R9. An RC circuit (a low-pass filter) constituted by the resistor R6 and the capacitor C6 removes high frequency components from the voltage (current detection signal) generated across the resistor R9 to generate a detection voltage Vcs, and supplies the detection voltage Vcs to a terminal CS. The detection voltage Vcs is a voltage that corresponds to the current flowing through the switching transistor. Since the detection voltage Vcs is a positive voltage, the PFC circuit 7A including the controller 700A corresponds to a positive voltage control type PFC circuit.

One end of the resistor R5 and one end of the capacitor C3 are connected to a terminal EO. The other end of the resistor R5 is connected to one end of the capacitor C4. The other end of the capacitor C3 and the other end of the capacitor C4 are connected to the ground terminal. A power supply voltage Vcc is supplied to the terminal VCC, and the terminal GND is connected to the ground terminal.

### Controller

A specific configuration of the controller 700A will be described below.

The controller 700A includes a Zener diode 701, a comparator 702, a band gap reference voltage circuit 703, a constant voltage circuit 704, and a thermal shutdown circuit 705. An anode of the Zener diode 701 is connected to the ground terminal, and a cathode of the Zener diode 701 is connected to the terminal VCC.

The Zener diode 701 clamps the power supply voltage Vcc to a Zener voltage. An inverting input terminal (−) of the comparator 702, the band gap reference voltage circuit 703, and the constant voltage circuit 704 are connected to the terminal VCC.

The comparator 702 is a hysteresis comparator, which compares the power supply voltage Vcc with a threshold voltage and outputs an undervoltage lockout signal UVLO indicating a comparison result. If the power supply voltage Vcc is equal to or higher than the threshold voltage, a level of the undervoltage lockout signal UVLO becomes a low level (a level indicating a normal state), and if the power supply voltage Vcc is lower than the threshold voltage, the level of the undervoltage lockout signal UVLO becomes a high level (a level indicating an abnormal state). The threshold voltage used by the comparator 702 transitions between a first threshold voltage Vth1 (e.g., 8 V) and a second threshold voltage Vth2 (e.g., 13 V) depending on the level of the undervoltage lockout signal UVLO.

The band gap reference voltage circuit 703 uses the power supply voltage Vcc to generate a reference voltage, and supplies the generated reference voltage to the constant voltage circuit 704.

The constant voltage circuit 704 uses the power supply voltage Vcc and the reference voltage to generate a constant voltage, and supplies the generated constant voltage to each part of the controller 700A.

The thermal shutdown circuit 705 detects an ambient temperature, and outputs a high-level (a level indicating an abnormal state) thermal shutdown signal TSD if the ambient temperature is equal to or higher than a threshold temperature, and outputs a low-level (a level indicating a normal state) thermal shutdown signal TSD if the ambient temperature is lower than the threshold temperature.

The controller 700A further includes a comparator 706, a startup overvoltage reduction circuit 707, a comparator 708, and a comparator 709.

The comparator 706 compares the detection voltage Vs with a threshold voltage Vth3 (e.g., 2.25 V) and outputs a comparison result to the startup overvoltage reduction circuit 707. If the detection voltage Vs is equal to or higher than the threshold voltage Vth3, a level of an output signal of the comparator 706 becomes a high level (a level indicating an abnormal state), and if the detection voltage Vs is lower than the threshold voltage Vth3, the level of the output signal of the comparator 706 becomes a low level (a level indicating a normal state).

The startup overvoltage reduction circuit 707 outputs a startup overvoltage reduction signal OVR. Based on the output signal of the comparator 706 and an output voltage Vcomp of a comparator 715 to be described later, when the detection voltage Vs rises to the threshold voltage Vth3 at startup, the startup overvoltage reduction circuit 707 sets the startup overvoltage reduction signal OVR to a high level (a level indicating an abnormal state) until a second voltage V2 to be described later drops to a constant voltage Vburst to be described later and, otherwise, sets the startup overvoltage reduction signal OVR to a low level (a level indicating a normal state).

The comparator 708 compares the detection voltage Vs with a threshold voltage Vth4 (e.g., 0.3 V) and outputs a short-circuit protection signal SP, which is a comparison result. If the detection voltage Vs is equal to or higher than the threshold voltage Vth4, a level of the short-circuit protection signal SP becomes a low level (a level indicating a normal state), and if the detection voltage Vs is lower than the threshold voltage Vth4, the level of the short-circuit protection signal SP becomes a high level (a level indicating an abnormal state).

The comparator 709 is a hysteresis comparator, which compares the detection voltage Vs with a threshold voltage and outputs a static overvoltage protection signal SOVP indicating a comparison result. If the detection voltage Vs is equal to or higher than the threshold voltage, a level of the static overvoltage protection signal SOVP becomes a high level (a level indicating an abnormal state), and if the detection voltage Vs is lower than the threshold voltage, the level of the static overvoltage protection signal SOVP becomes a low level (a level indicating a normal state). The threshold voltage used by the comparator 709 transitions between a threshold voltage Vth5 (e.g., 2.6 V) and a threshold voltage Vth6 (e.g., 2.7 V) depending on the level of the static overvoltage protection signal SOVP.

The controller 700A further includes an error amplifier circuit 710, an OR gate 711, an NMOS transistor 712, an arithmetic circuit 713, a Zener diode 714, a comparator 715, and a drive circuit DRV1.

The error amplifier circuit 710 amplifies an error between the detection voltage Vs, which corresponds to the output voltage Vdc of the step-up type DC/DC converter (switching regulator) provided in the PFC circuit 7A, and a reference voltage Vref1 to generate the second voltage V2. An amplification factor of the error amplifier circuit 710 may be 1. The error amplifier circuit 710 supplies the second voltage V2 to the terminal EO and the arithmetic circuit 713.

The OR gate 711 outputs a logical sum of the undervoltage lockout signal UVLO and the startup overvoltage reduction signal OVR to a gate of the NMOS transistor 712. A drain of the NMOS transistor 712 is connected to the terminal EO, and a source of the NMOS transistor 712 is connected to the ground terminal. The NMOS transistor 712 is a switch configured to discharge the second voltage applied to the terminal EO. Therefore, when at least one selected from the group of the undervoltage lockout signal UVLO and the startup overvoltage reduction signal OVR is at a high level, the NMOS transistor 712 is turned on and the second voltage V2 drops.

The arithmetic circuit 713 generates a third voltage by multiplying the AC voltage (the first voltage) Vmult by the second voltage V2, and generates a fourth voltage V4 by adding an offset voltage Voffset to the third voltage.

The fourth voltage V4 is connected to an inverting input terminal of the comparator 715. A cathode of the Zener diode 714 is connected to the inverting input terminal of the comparator 715, and an anode of the Zener diode 714 is connected to the ground terminal. The Zener diode 714 clamps the fourth voltage V4 to a Zener voltage.

The comparator 715 compares the detection voltage Vcs, which corresponds to the current flowing through the switching transistor M1, with the fourth voltage V4, and outputs a voltage Vcomp indicating a comparison result.

The drive circuit DRV1 drives the switching transistor M1 to be turned on or off, such that the switching transistor M1 turned off each time the detection voltage Vcs becomes higher than the fourth voltage V4, according to the voltage Vcomp which is the output of the comparator 715. Note that turning off refers to switching from an on state to an off state. In other words, the drive circuit DRV1 turns off the switching transistor M1 based on the voltage Vcomp which is the output of the comparator 715. There are no particular limitations on the configuration of the drive circuit DRV1, and any known techniques may be used for the drive circuit DRV1.

FIG. 2 shows an example of the drive circuit DRV1. The drive circuit DRV1 includes a comparator 716, a one-shot circuit 717, a timer 718, an OR gate 719, a flip-flop 720, an AND gate 721, a pre-driver 722, a gate clamp circuit 723, a PMOS transistor (P-channel MOSFET) 724, an NMOS transistor 725, and a resistor 726.

The comparator 716 is a hysteresis comparator, and compares a voltage applied to the terminal ZCD with a threshold voltage and outputs a comparison result to the one-shot circuit 717. If the voltage applied to the terminal ZCD is equal to or higher than the threshold voltage, a level of an output signal of the comparator 716 becomes a low level, and if the voltage applied to the terminal ZCD is lower than the threshold voltage, the level of the output signal of the comparator 716 becomes a high level. The threshold voltage used by the comparator 716 transitions between a threshold voltage Vth7 (e.g., 0.67 V) and a threshold voltage Vth8 (e.g., 0.9 V) depending on the level of the output signal of the comparator 716.

When the level of the output signal of the comparator 716 becomes the high level, the one-shot circuit 717 supplies a one-shot pulse to the first input terminal of the OR gate 719.

When the timer 718 has timed a certain period of time, it supplies a high-level signal to a second input terminal of the OR gate 719. The timing of the timer 718 is reset each time the pre-driver 722 receives a high-level signal from the AND gate 721.

The OR gate 719 supplies a logical sum of output signals of the one-shot circuit 717 and the timer 718 to a set terminal (S) of the RS flip-flop 720. A reset terminal (R) of the RS flip-flop 720 is supplied with the voltage Vcomp, which is the output of the comparator 715. An output (Q) of the RS flip-flop 720 transitions to a high level at each positive edge of a voltage applied to the set terminal (S), and transitions to a low level at each positive edge of a voltage applied to the reset terminal (R).

The AND gate 721 supplies the pre-driver 722 with a logical product of an inverted signal of the undervoltage lockout signal UVLO, an output signal of the RS flip-flop 720, an inverted signal of the static overvoltage protection signal SOVP, an inverted signal of the short-circuit protection signal SP, an inverted signal of the thermal shutdown signal TSD, and a PFC off signal PFCOFF_H to be described later.

The pre-driver 722 drives the PMOS transistor 724 and the NMOS transistor 725 to be complementarily turned on or off based on an output of the AND gate 721. Specifically, when the output of the AND gate 721 is at a high level, the pre-driver 722 turns the PMOS transistor 724 on and the NMOS transistor 725 off, thereby setting a voltage of the terminal OUT to a high level and turning the switching transistor M1 on. On the other hand, when the output of the AND gate 721 is at a low level, the pre-driver 722 turns the PMOS transistor 724 off and the NMOS transistor 725 on, thereby setting the voltage of the terminal OUT to a low level and turning the switching transistor M1 off.

A source of the PMOS transistor 724 is connected to the gate clamp circuit 723, and a drain of the PMOS transistor 724 is connected to a drain of the NMOS transistor 725, the terminal OUT, and one end of the resistor 726. A source of the NMOS transistor 725 is connected to the ground terminal and the other end of the resistor 726. The gate clamp circuit 723 generates a high-level voltage that is applied to the terminal OUT from the power supply voltage Vcc. The gate clamp circuit 723 clamps the high-level voltage applied to the terminal OUT to a constant voltage so that the high-level voltage applied to the terminal OUT does not exceed a gate-source breakdown voltage of the switching transistor M1 when the power supply voltage Vcc rises.

The controller 700A includes a comparator 727 and a terminal PFCOFF as an external terminal. A non-inverting input terminal of the comparator 727 is connected to the terminal PFCOFF. The comparator 727 compares a control signal Poff input to the terminal PFCOFF with a threshold voltage Vth9, and outputs a PFC off signal PFCOFF_H. The PFC off signal PFCOFF_H is input to the AND gate 721. As a result, when the control signal Poff is at a low level, a level of the PFC off signal PFCOFF_H becomes a low level, and when the control signal Poff is at a high level, the level of the PFC off signal PFCOFF_H becomes a high level. When the control signal Poff is at a low level, the PFC circuit 7A (the controller 700A) is in a standby state.

### Arithmetic Circuit

The above is a description of the configuration of the PFC circuit 7A. Subsequently, an internal configuration of the arithmetic circuit 713 will be described. First, a specific example of a configuration of an offset voltage generation circuit 713A provided in the arithmetic circuit 713 will be described.

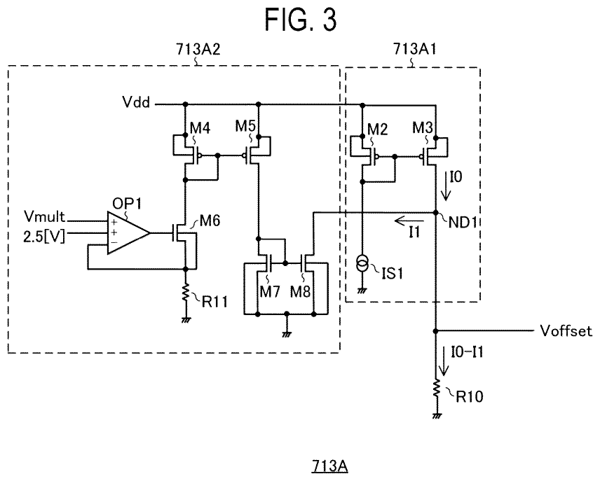

FIG. 3 shows an example of the offset voltage generation circuit 713A. The offset voltage generation circuit 713A includes a constant current generation circuit 713A1, a first current generation circuit 713A2, and a resistor R10.

The constant current generation circuit 713A1 includes a current mirror circuit constituted by PMOS transistors M2 and M3, and a current source IS1. A constant voltage Vdd output from the constant voltage circuit 704 is applied to a source and a back gate of the PMOS transistor M2 and a source and a back gate of the PMOS transistor M3. A gate and a drain of the PMOS transistor M2 and a gate of the PMOS transistor M3 are connected to one end of the current source IS1. The other end of the current source IS1 is connected to the ground terminal. A drain of the PMOS transistor M3 and one end of the resistor R10 are connected to a node ND1. The other end of the resistor R10 is connected to the ground terminal. The constant current generation circuit 713A1 generates a constant current I0 and supplies the constant current I0 to the node ND1. A value of the constant current I0 is not particularly limited, but for example, if a value of a constant current output by the current source IS1 is 1 μA and a current mirror ratio is 6:1, the value of the constant current I0 is 167 nA.

The first current generation circuit 713A2 includes an operational amplifier OP1, a sweep-out type current mirror circuit constituted by PMOS transistors M4 and M5, an NMOS transistor M6, a resistor R11, and a pull-out type current mirror circuit constituted by NMOS transistors M7 and M8. The constant voltage Vdd output from the constant voltage circuit 704 is applied to a source and a back gate of the PMOS transistor M4 and a source and a back gate of the PMOS transistor M5. A gate and a drain of a PMOS transistor M4 and a gate of the PMOS transistor M5 are connected to a drain of the NMOS transistor M6.

A source and a back gate of the NMOS transistor M6 are connected to one end of the resistor R11 and an inverting input terminal of the operational amplifier OP1. The other end of the resistor R11 is connected to the ground terminal. A first non-inverting input terminal of the operational amplifier OP1 is supplied with the voltage Vmult, and a second non-inverting input terminal of the operational amplifier OP1 is supplied with a constant voltage of, for example, 2.5 V. An output terminal of the operational amplifier OP1 is connected to a gate of the NMOS transistor M6. The operational amplifier OP1 outputs a signal obtained by amplifying a difference between a voltage obtained by adding the voltage Vmult and the constant voltage of, for example, 2.5 V, and a voltage supplied to the inverting input terminal.

A drain of the PMOS transistor M5 is connected to a drain and a gate of the NMOS transistor M7 and a gate of the NMOS transistor M8. A source and a back gate of the NMOS transistor M7 and a source and a back gate of the NMOS transistor M8 are connected to the ground terminal. A drain of the NMOS transistor M8 is connected to the node ND1. The first current generation circuit 713A2 generates a first current I1 and pulls out the first current I1 from the node ND1. The first current I1 varies according to the voltage (AC voltage) Vmult. Specifically, as the voltage Vmult becomes higher, the first current I1 becomes larger. In the example shown in FIG. 3, as the voltage Vmult becomes higher, the first current I1 becomes linearly larger.

A current obtained after the first current I1 is pulled out from the constant current I0, that is, a differential current (I0−I1), flows from the node ND1 to the resistor R10. A product of the differential current (I0−I1) and a resistance value of the resistor R10 is the offset voltage Voffset. Therefore, the offset voltage Voffset varies according to the voltage Vmult. Specifically, as the voltage Vmult becomes higher, the offset voltage Voffset becomes lower. In the example shown in FIG. 3, as the voltage Vmult becomes higher, the offset voltage Voffset becomes linearly lower.

A range of the offset voltage Voffset is not particularly limited, but in the example shown in FIG. 3, for example, if the value of the constant current I0 is 167 nA as described above, a current mirror ratio of the sweep-out type current mirror circuit in the first current generation circuit 713A2 is 10:1, a resistance value of the resistor R11, which is a current source connected to the sweep-out type current mirror circuit, is 2 MΩ, a pull-out type current mirror ratio in the first current generation circuit 713A2 is 1:1, and the resistance value of the resistor R10 is 161.2 kΩ, the offset voltage Voffset varies in a range of 6.9 mV to 26.8 mV.

If a designed minimum value of the offset voltage Voffset is set to 6.9 mV as in the above-described example, for example, an actual minimum value of the offset voltage Voffset due to variations in the circuit constants can be made zero or greater.

If the minimum value of the offset voltage Voffset becomes smaller than zero, the offset voltage generation circuit 713A does not operate normally in the example shown in FIG. 3, so it is desirable that the minimum value of the offset voltage Voffset is equal to or greater than zero. It is also possible to configure the circuit so that no malfunction occurs when the minimum value of the offset voltage Voffset becomes smaller than zero, so it is also possible to make the minimum value of the offset voltage Voffset smaller than zero.

In addition, a trimming element configured to adjust the circuit constant may be provided in the offset voltage generation circuit 713A to suppress variations in the circuit constant and set the designed minimum value of the offset voltage Voffset to zero or close to zero. An example of the trimming element may include at least one fuse provided in a parallel circuit of a plurality of resistors configured to adjust a resistance value of a resistor that is a current source connected to the sweep-out type current mirror circuit in the first current generation circuit 713A2. The fuse can be cut by, for example, laser trimming.

The above is a description of the configuration of the offset voltage generation circuit 713A. Subsequently, a specific example of a configuration of a circuit other than the offset voltage generation circuit 713A of the arithmetic circuit 713 will be described. In addition to the offset voltage generation circuit 713A, the arithmetic circuit 713 includes a first arithmetic circuit 713B, a first conversion circuit 713C, a second conversion circuit 713D, and a second arithmetic circuit 713E.

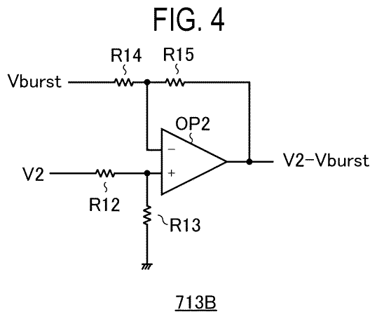

FIG. 4 shows an example of the first arithmetic circuit 713B. The first arithmetic circuit 713B includes resistors R12 to R15 and an operational amplifier OP2. The second voltage V2 is applied to one end of the resistor R12. The other end of the resistor R12 and one end of the resistor R13 are connected to a non-inverting input terminal of the operational amplifier OP2. The other end of the resistor R13 is connected to the ground terminal. A constant voltage Vburst is applied to one end of the resistor R14. The other end of the resistor R14 and one end of the resistor R15 are connected to an inverting input terminal of the operational amplifier OP2. The other end of the resistor R15 is connected to an output terminal of the operational amplifier OP2. The first arithmetic circuit 713B outputs a voltage (V2−Vburst) obtained by subtracting the constant voltage Vburst from the second voltage V2.

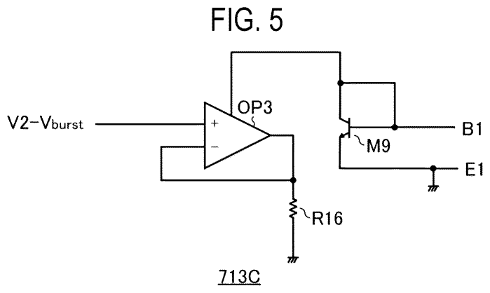

FIG. 5 shows an example of the first conversion circuit 713C. The first conversion circuit 713C includes an operational amplifier OP3, a resistor R16, and an NPN bipolar transistor M9. The voltage (V2−Vburst) is applied to a non-inverting input terminal of the operational amplifier OP3. One end of the resistor R16 is connected to an inverting input terminal and an output terminal of the operational amplifier OP3. The other end of the resistor R16 is connected to the ground terminal. A collector and a base of the NPN bipolar transistor M9 are connected to a power supply terminal of the operational amplifier OP3. An emitter of the NPN bipolar transistor M9 is connected to the ground terminal. The first conversion circuit 713C converts the voltage (V2−Vburst) into a current (I2−Iburst) and outputs the current (I2−Iburst) as a base current of the NPN bipolar transistor M9.

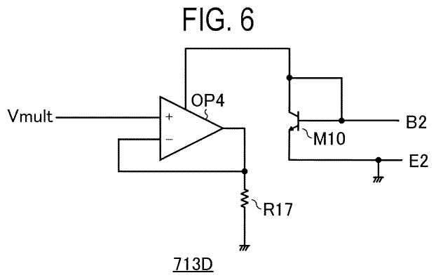

FIG. 6 shows an example of the second conversion circuit 713D. The second conversion circuit 713D includes an operational amplifier OP4, a resistor R17, and an NPN bipolar transistor M10. The voltage Vmult is applied to a non-inverting input terminal of the operational amplifier OP4. One end of the resistor R17 is connected to an inverting input terminal and an output terminal of the operational amplifier OP4. The other end of the resistor R17 is connected to the ground terminal. A collector and a base of the NPN bipolar transistor M10 are connected to a power supply terminal of the operational amplifier OP4. An emitter of the NPN bipolar transistor M10 is connected to the ground terminal. The second conversion circuit 713D converts the voltage Vmult to a current Imult, and outputs the current Imult as a base current of the NPN bipolar transistor M10.

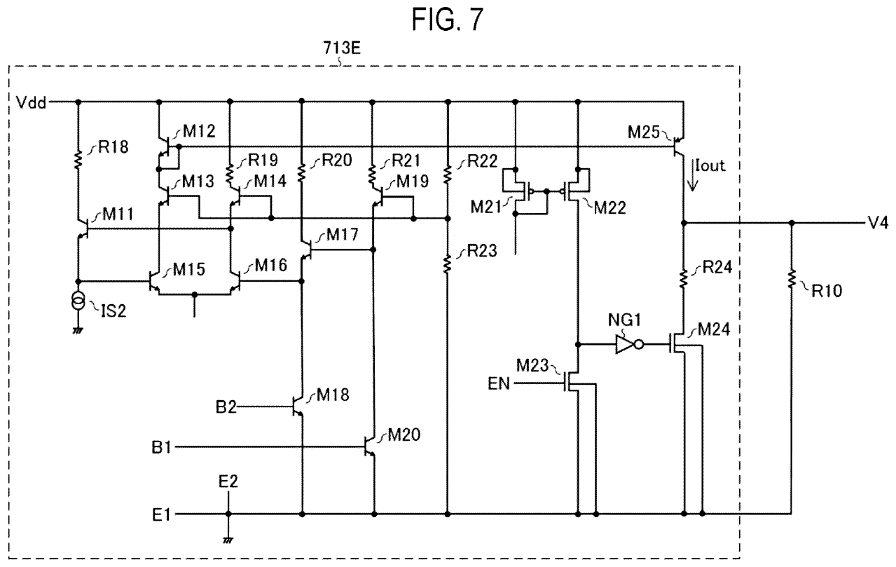

FIG. 7 shows an example of the second arithmetic circuit 713E. The second arithmetic circuit 713E includes resistors R18 to R24, a current source IS2, NPN bipolar transistors M11 to M20, PMOS transistors M21 and M22, NMOS transistors M23 and M24, a PNP bipolar transistor M25, and a NOT gate NG1.

The constant voltage Vdd output from the constant voltage circuit 704 is applied to one end of each of the resistors R18 to R22, a collector of the NPN bipolar transistor M12, a source and a back gate of the PMOS transistor M21, a source and a back gate of the PMOS transistor M22, and an emitter of the PNP bipolar transistor M25. The other end of the resistor R18 is connected to the collector of the NPN bipolar transistor M11. The emitter of the NPN bipolar transistor M11 is connected to one end of the current source IS2 and the base of the NPN bipolar transistor M15. The other end of the current source IS2 is connected to the ground terminal.

A base and an emitter of the NPN bipolar transistor M12 are connected to the base of the PNP bipolar transistor M25 and the collector of the NPN bipolar transistor M13. The emitter of the NPN bipolar transistor M13 is connected to the collector of the NPN bipolar transistor M15. The emitter of the NPN bipolar transistor M15 is connected to the emitter of the NPN bipolar transistor M16. The other end of the resistor R19 is connected to the collector of the NPN bipolar transistor M14. The emitter of the NPN bipolar transistor M14 is connected to the base of the NPN bipolar transistor M11 and the collector of the NPN bipolar transistor M16.

The other end of the resistor R20 is connected to the collector of the NPN bipolar transistor M17. The emitter of the NPN bipolar transistor M17 is connected to the base of the NPN bipolar transistor M16 and the collector of the NPN bipolar transistor M18. The emitter of the NPN bipolar transistor M18 is connected to the ground terminal. The base of the NPN bipolar transistor M18 is connected to the base and collector of the NPN bipolar transistor M10 in the second conversion circuit 713D. The NPN bipolar transistors M10 and M18 form a current mirror circuit.

The other end of the resistor R21 is connected to the collector of the NPN bipolar transistor M19. The emitter of the NPN bipolar transistor M19 is connected to the base of the NPN bipolar transistor M17 and the collector of the NPN bipolar transistor M20. The emitter of the NPN bipolar transistor M20 is connected to the ground terminal. The base of the NPN bipolar transistor M20 is connected to the base and collector of the NPN bipolar transistor M9 in the first conversion circuit 713C. The NPN bipolar transistors M9 and M20 form a current mirror circuit.

The other end of the resistor R22 is connected to one end of the resistor R23, the base of the NPN bipolar transistor M13, the base of the NPN bipolar transistor M14, and the base of the NPN bipolar transistor M19. The other end of the resistor R23 is connected to the ground terminal.

A gate and a drain of the PMOS transistor M21 are connected to a gate of the PMOS transistor M22. The PMOS transistors M21 and M22 constitute a current mirror circuit. A drain of the PMOS transistor M22 is connected to a drain of the NMOS transistor M23 and an input terminal of the NOT gate. An enable signal EN is supplied to a gate of the NMOS transistor M23. A source and a back gate of the NMOS transistor M23 are connected to the ground terminal. An output terminal of the NOT gate is connected to a gate of the NMOS transistor M24. A source and a back gate of the NMOS transistor M24 are connected to the ground terminal. A drain of the NMOS transistor M24 is connected to one end of the resistor R24. The other end of the resistor R24 is connected to a collector of the PNP bipolar transistor M25 and the one end of the resistor R10. The other end of the resistor R10 is connected to the ground terminal.

The second arithmetic circuit 713E multiplies the current (I2−Iburst) by the current Imult, and outputs an output current lout, which is the multiplication result, to the resistor R10. The resistor R10 converts the output current Iout into a voltage (K×Vmult (V2−Vburst)). The constant K is determined by a ratio between a resistance value of the resistor R16 in the first conversion circuit 713C and the resistance value of the resistor R10, and a ratio between a resistance value of the resistor R17 in the second conversion circuit 713D and the resistance value of the resistor R10. A current I3 output by the current source IS2 in the second arithmetic circuit 713E is a current proportional to a peak value (maximum value) of the voltage Vmult. The second arithmetic circuit 713E can be switched between an enabled state and a disabled state by the enable signal EN.

The resistor R10 shown in FIG. 7 is the same as the resistor R10 provided in the offset voltage generation circuit 713A shown in FIG. 3. Therefore, the offset voltage Voffset is also applied to the resistor R10. Therefore, the fourth voltage V4 generated in the resistor R10 as a voltage across the resistor R10 is expressed by the following equation.

V4=K×Vmult (V2−Vburst)+Voffset

Here, in order to explain an effect of the PFC circuit 7A, a circuit in which the offset voltage generation circuit 713A is removed from the PFC circuit 7A will be compared with the PFC circuit 7A.

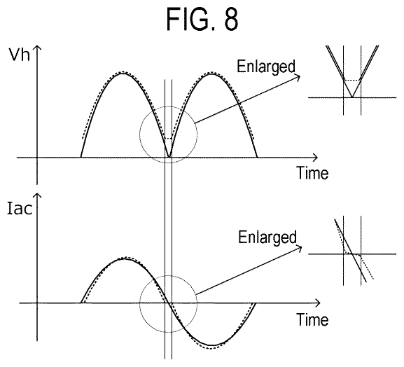

In the circuit in which the offset voltage generation circuit 713A is removed from the PFC circuit 7A, an on-time of the switching transistor M1 is shortened due to the operation of the drive circuit DRV1 when the first voltage Vh is near 0 V. Therefore, when the first voltage Vh is near 0 V, the capacitor 6 provided on an output side of the rectifier circuit 5 cannot be sufficiently discharged, and as a result, a current output from the rectifier circuit 5 stops temporarily, thereby causing distortion in the input current Iac (see a dotted line in FIG. 8).

On the other hand, in the PFC circuit 7A, when the first voltage Vh is near 0 V, the offset voltage Voffset becomes high and the fourth voltage V4 also becomes high, so the on-time of the switching transistor M1 is lengthened due to the operation of the drive circuit DRV1. Therefore, when the first voltage Vh is near 0 V, the capacitor 6 provided on the output side of the rectifier circuit 5 can be sufficiently discharged, and as a result, a current is smoothly output from the rectifier circuit 5, thereby suppressing distortion of the input current Iac (see a solid line in FIG. 8). In other words, the controller 700A can suppress THD (Total Harmonic Distortion) of the PFC circuit 7A.

Note that since it is not necessary to make the offset voltage Voffset high when the first voltage Vh is not near 0 V, it is preferable that the offset voltage Voffset is variable as in the above-described embodiment. However, the offset voltage Voffset may be fixed by allowing the addition of an unnecessary offset voltage Voffset when the first voltage Vh is not near 0 V.

### SECOND COMPARATIVE EXAMPLE

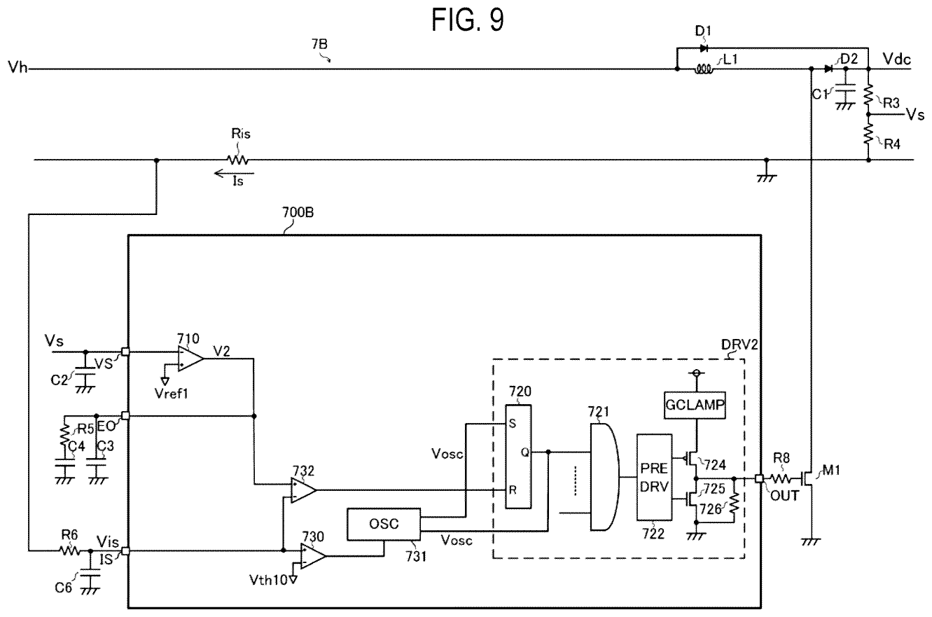

FIG. 9 is a diagram showing a configuration of a PFC circuit 7B according to a second comparative example. The PFC circuit 7B is different from the first comparative example in that the former does not include the inductor L2, but includes a sense resistor Ris and a controller 700B. The controller 700B further includes a terminal IS instead of the terminal CS as an external terminal.

One end of the sense resistor Ris is connected to the ground terminal. The other end of the sense resistor Ris is connected to one end of the resistor R6. The other end of the resistor R6 is connected to the terminal IS. When the switching transistor M1 is in the on state, a current Is flows through the sense resistor Ris from the ground side, so a detection voltage Vis generated at the terminal IS becomes a negative voltage. Therefore, the PFC circuit 7B shown in FIG. 9 corresponds to a negative voltage control type PFC circuit.

The controller 700B includes an error amplifier circuit 710, a comparator 730, an OSC (oscillator) 731, a comparator 732, and a drive circuit DRV2. The controller 700B further includes terminals VS, EO, IS, and OUT as external terminals.

Similar to the first comparative example, the detection voltage Vs generated at the terminal VS and the reference voltage Vref1 are input to the error amplifier circuit 710, and a voltage V2 is output from the error amplifier circuit 710. The voltage V2 and the detection voltage Vis are input to the comparator 732, and the output of the comparator 732 is input to the reset terminal of the flip-flop 720 in the drive circuit DRV2. The detection voltage Vis and a negative reference voltage Vth10 are input to the comparator 730, and an output of the comparator 730 is input to the OSC 731. An oscillation signal Vosc output from the OSC 731 is connected to the set terminal and Q output terminal of the flip-flop 720.

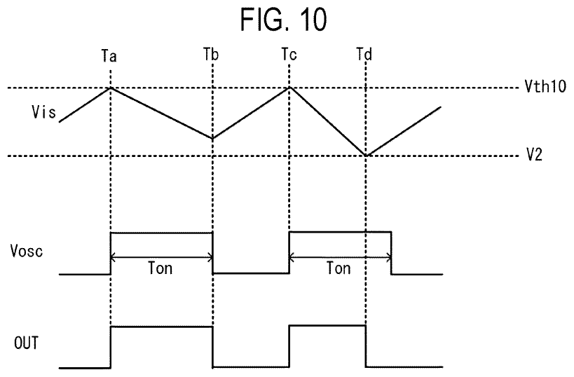

An example of an operation of the PFC circuit 7B configured as described above is shown in a timing chart of FIG. 10. FIG. 10 shows an example of waveforms of the detection voltage Vis, the oscillation signal Vosc, and the voltage at the terminal OUT in order from the top.

When the switching transistor M1 is in the off state, the current Is decreases, and the detection voltage Vis rises toward 0 V. When the detection voltage Vis exceeds the reference voltage Vth10 (for example, −10 mV) at timing Ta, it is detected by the comparator 730, and the oscillation signal Vosc is raised to a high level by the OSC 731. As a result, the voltage at the terminal OUT rises to a high level, and the switching transistor M1 is turned on. Turning on refers to switching from an off state to an on state.

As a result, the current Is increases and the detection voltage Vis drops. Then, when a predetermined ON width time Ton has elapsed before the detection voltage Vis reaches the voltage V2 (=negative voltage), the oscillation signal Vosc is lowered to a low level by the OSC 731 (timing Tb). As a result, the Q output of the flip-flop 720 is set to a low level, the voltage at the terminal OUT falls to a low level, and the switching transistor M1 is turned off.

Then, the current Is decreases, and the detection voltage Vis rises toward 0 V. When the detection voltage Vis exceeds the reference voltage Vth10 at timing Ta, it is detected by the comparator 730, and the oscillation signal Vosc is raised to a high level by the OSC 731 (timing Tc). As a result, the voltage at the terminal OUT rises to a high level, and the switching transistor M1 is turned on.

Then, the current Is increases, and the detection voltage Vis drops. Then, when the detection voltage Vis reaches the voltage V2 before the ON width time Ton has elapsed, it is detected by the comparator 732, and the Q output is set to a low level by the reset of the flip-flop 720. As a result, the voltage at the terminal OUT falls to a low level, and the switching transistor M1 is turned off (timing Td).

In this way, in the configuration according to the second comparative example (FIG. 9), in the negative voltage control type PFC circuit 7B, it is possible to control the turn-off of the switching transistor M1 without using the voltage Vmult as in the first comparative example. However, since the voltage Vmult (the terminal MULT) is not used, the configuration is not one in which the THD is improved as in the first comparative example.

### Embodiment of the Present Disclosure

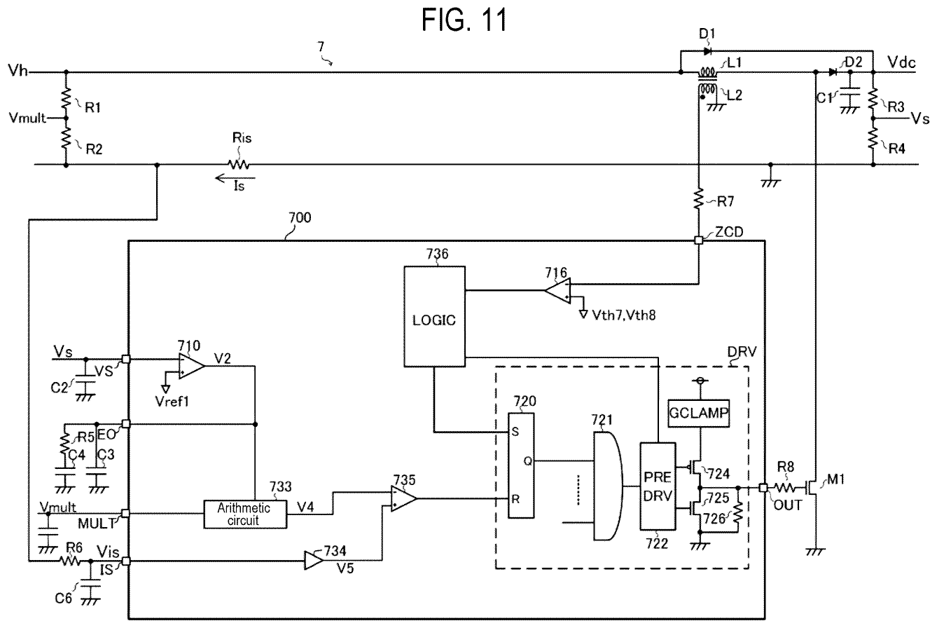

Considering the above-described problems, in the present embodiment, a configuration is realized that improves the THD in a negative voltage control type PFC circuit. FIG. 11 is a diagram showing a configuration of a PFC circuit 7 according to an embodiment of the present disclosure. The PFC circuit 7 includes a controller 700.

The controller 700 includes a terminal MULT as an external terminal. In the PFC circuit 7, a voltage Vh is divided by resistors R1 and R2 as in the first comparative example to generate a voltage Vmult, and the voltage Vmult is applied to the terminal MULT. The controller 700 includes an error amplifier circuit 710, an arithmetic circuit 733, an inverting amplifier 734, a comparator 735, and a drive circuit DRV. In addition, the PFC circuit 7 is provided with an inductor L2 and a resistor R7 as in FIG. 2, and the controller 700 includes a terminal ZCD and a comparator 716 as in FIG. 2. A logic part 736 in the controller 700 controls a set terminal of a flip-flop 720 based on the output of the comparator 716.

As in the first comparative example, a voltage V2 output from the error amplifier circuit 710 and the voltage Vmult are input to the arithmetic circuit 733. As in the first comparative example, the arithmetic circuit 733 calculates a voltage V4 according to the following equation.

V4=K×Vmult (V2−Vburst)+Voffset

The inverting amplifier 734 is a circuit configured to invert and amplify a detection voltage Vis, which is a negative voltage, to convert the same into a detection voltage V5, which is a positive voltage. The voltage V4 is input to an inverting input terminal of the comparator 735, and the detection voltage V5 is input to the non-inverting input terminal thereof. An output of the comparator 735 is input to a reset terminal of the flip-flop 720 in the drive circuit DRV.

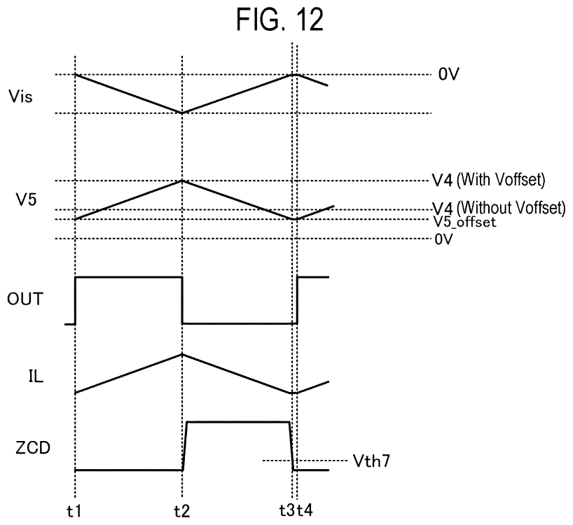

FIG. 12 is a timing chart showing an example of an operation of the PFC circuit 7 according to the present embodiment. FIG. 12 shows an example of waveforms of the detection voltage Vis, the detection voltage V5, a voltage at a terminal OUT, an inductor current IL flowing through an inductor L1, and a voltage at the terminal ZCD in order from the top.

When the voltage at the terminal OUT rises to a high level at timing t1 and the switching transistor M1 is turned on, the inductor current IL increases, the detection voltage Vis drops from 0 V, and the positive detection voltage V5 rises accordingly. Then, when the detection voltage V5 exceeds the voltage V4, the flip-flop 720 is reset, the voltage at the terminal OUT falls to a low level, and the switching transistor M1 is turned off (timing t2).

Then, the inductor current IL decreases, and the voltage at the terminal ZCD rises. In addition, the detection voltage Vis rises toward 0 V, and the detection voltage V5 drops. The comparator 716 monitors an auxiliary winding voltage (voltage of the inductor L2) from the terminal ZCD, and when the inductor current IL crosses zero, the voltage at the terminal ZCD drops, which is detected by the comparator 716 (timing t3). When the zero crossing of the inductor current IL is detected, the flip-flop 720 is set by the logic part 736, the voltage at the terminal OUT rises to a high level, and the switching transistor M1 is turned on (timing t4).

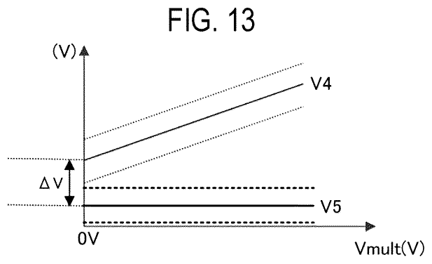

FIG. 12 shows V4 with and without an offset voltage Voffset. FIG. 12 also shows an offset voltage V5_offset (e.g., 200 mV), which is a value of the detection voltage V5 when the detection voltage Vis=0 V. As shown in FIG. 13, when the voltage Vmult is 0 V, a value of the voltage V4 calculated by the arithmetic circuit 733 is Voffset, and it is necessary to secure an offset difference ΔV expressed as ΔV=Voffset−V5_offset. If the offset difference ΔV is secured, when the voltage Vh is close to 0 V, i.e., when Vmult is close to 0 V, the ON width of the switching transistor M1 becomes longer, thereby improving the THD.

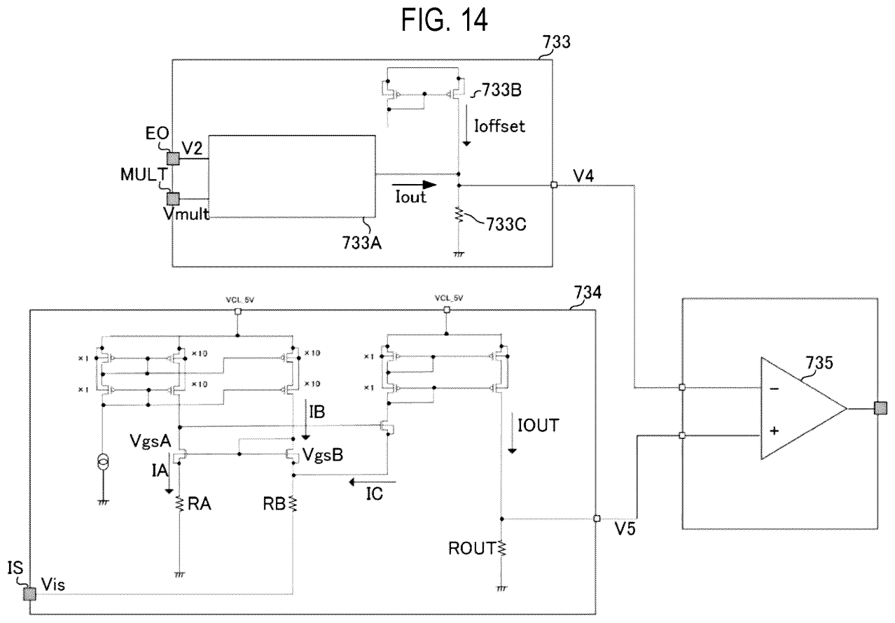

FIG. 14 is a diagram showing a specific example of a configuration of the arithmetic circuit 733 and the inverting amplifier 734. The arithmetic circuit 733 includes an arithmetic processor 733A, an offset generator 733B, and a resistor 733C.

The arithmetic processor 733A outputs an output current Iout toward the resistor 733C, similar to the second arithmetic circuit 713E (FIG. 7) of the first comparative example. The offset generator 733B outputs an offset current Ioffset toward the resistor 733C. The output current Iout and the offset current Ioffset are combined and flow through the resistor 733C. A voltage generated across the resistor 733C is output as the voltage V4.

That is, assuming the resistance value of the resistor 733C to be R,

V4=R×(Iout+Ioffset)

=R×Iout+R×Ioffset

=K×Vmult(V2−Vburst)+Voffset

As described above, it is necessary to secure the offset difference ΔV, but due to variations between products, a setting step is required to set the offset difference ΔV to a desired value. Such a setting method will be described below.

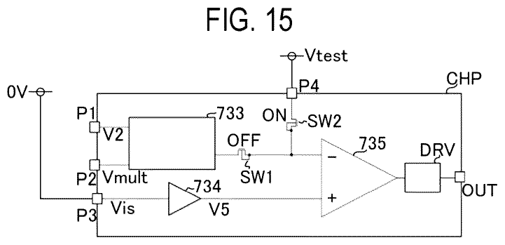

FIG. 15 is a diagram showing a configuration related to a step of setting the offset difference ΔV. Here, the controller 700 shown in FIG. 11 is a semiconductor device including a chip that integrates the internal configuration shown in FIG. 11. FIG. 15 shows that the arithmetic circuit 733, the inverting amplifier 734, the comparator 735, and the drive circuit DRV are integrated in the chip CHP as described above. The chip CHP is provided with pads, including an EO pad P1, a MULT pad P2, an IS pad P3, and a test pad P4. The EO pad P1, the MULT pad P2, and the IS pad P3 are connected to the terminals EO, MULT, and IS of the controller 700 by bonding wires, respectively. The test pad P4 is not connected to an external terminal by a bonding wire.

The chip CHP is also provided with a switch SW1 between the output terminal of the arithmetic circuit 733 and the inverting input terminal of the comparator 735, and a switch SW2 between the test pad P4 and the inverting input terminal of the comparator 735. When the chip CHP is normally used as the controller 700, the switch SW1 is in an on state and the switch SW2 is in an off state.

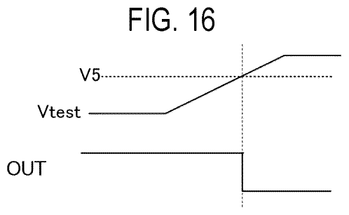

The setting step is performed in the state of the chip CHP. First, in a first step, as shown in FIG. 15, the switch SW1 is turned off and the SW2 is turned on, and a test voltage Vtest is applied to the test pad P4 with 0 V applied to the IS pad P3. The test voltage Vtest is swept so as to rise from 0 V. A voltage of the OUT terminal is monitored, and a value of Vtest is measured when a voltage level of the OUT terminal switches. This makes it possible to measure the voltage V5 when the detection voltage Vis=0 V, that is, the offset voltage V5_offset. FIG. 16 shows an example of a waveform when measuring the offset voltage V5_offset. When Vtest is swept and reaches V5 when the detection voltage Vis=0 V, the voltage level of the terminal OUT switches.

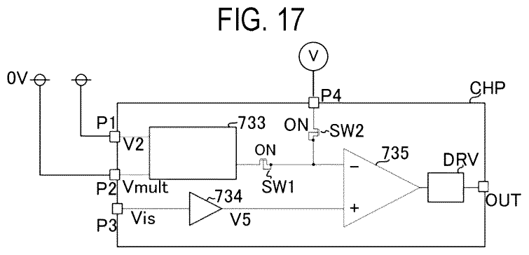

Next, in a second step, as shown in FIG. 17, the switches SW1 and SW2 are both turned on, and a voltage generated at the test pad P4 is measured with 0 V applied to the MULT pad P2. This makes it possible to measure the value of V4 when Vmult=0 V, that is, the offset voltage Voffset. At this time, the offset generator 733B shown in FIG. 14 performs the measurement by using the offset current Ioffset as a reference value.

Then, in a third step, the offset generator 733B adjusts (repairs) the offset current Ioffset so that the offset difference ΔV becomes a desired value based on the offset voltages V5_offset and Voffset measured as described above. This makes it possible to set the offset difference ΔV to a desired value.

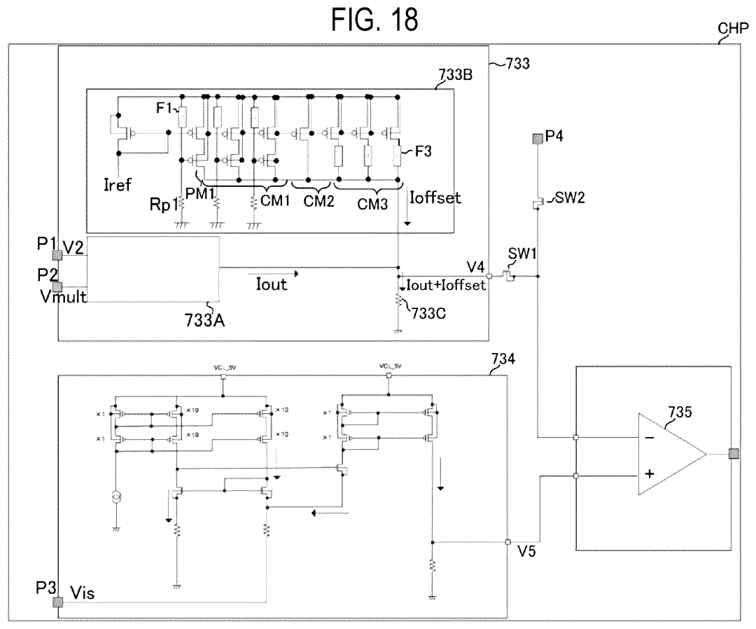

FIG. 18 is a diagram showing a specific example of a configuration of the offset generator 733B. The offset generator 733B shown in FIG. 18 includes current mirrors CM1 to CM3.

The current mirror CM1 is configured to mirror a reference current Iref by PMOS transistors on the input and output sides. The current mirror CM1 also includes a PMOS transistor PM1 whose source is connected to the drain of the PMOS transistor on the output side, a fuse F1 connected to a high potential side (upper side) of a gate of the PMOS transistor PM1, and a pull-down resistor Rp1 connected to a low potential side (lower side) of the gate of the PMOS transistor PM1. The PMOS transistor PM1 switches the current mirror CM1 between an enabled state and a disabled state depending on whether the fuse F1 is cut or not.

The current mirror CM2 is configured to mirror the reference current Iref by PMOS transistors on the input and output sides.

The current mirror CM3 is configured to mirror the reference current Iref by PMOS transistors on the input and output sides. The current mirror CM3 also includes a fuse F3 connected to the drain of the PMOS transistor on the output side. The current mirror CM3 is switched between a disabled state and an enabled state depending on whether the fuse F3 is cut or not.

As shown in FIG. 18, one current mirror CM2, three current mirrors CM1, and three current mirrors CM3 are provided. Note that the number of current mirrors is not limited thereto. A reference state is a state in which none of the fuses F1 and F3 are cut, in which case the offset current Ioffset generated is a reference value. In this case, since the current mirror CM1 is disabled (the PMOS transistor PM1 is turned off) and the current mirror CM3 is enabled, currents mirrored by the current mirrors CM2 and CM3 are combined to generate the offset current Ioffset.

When the fuse F1 is cut during repair, since the current mirror CM1 corresponding to the cut fuse F1 is enabled (PMOS transistor PM1 is turned on), a current mirrored by the current mirror CM1 is added to the currents mirrored by the current mirrors CM2 and CM3, thereby increasing the offset current Ioffset from the reference value.

When the fuse F3 is cut during the repair, since the current mirror CM3 corresponding to the cut fuse F3 is disabled, the offset current Ioffset is decreased from the reference value. In this way, it is possible to perform the repair such that the offset current Ioffset is increased or decreased by cutting the fuses F1 and F3.

Note that the offset current Ioffset may be repaired by providing a switch instead of a fuse and setting the switch to be turned on or off by using a logic circuit.

### Others

The various technical features disclosed in the present disclosure can be modified in various ways in addition to the embodiments described above without departing from the gist of the technical creation. That is, the embodiments described above should be considered to be illustrative in all respects and not restrictive. Further, the technical scope of the present disclosure is not limited to the embodiments described above, and it should be understood that the technical scope of the present disclosure includes all changes that fall within the meaning and range equivalent to the claims.

### SUPPLEMENTARY NOTES

As described above, according to one aspect of the present disclosure, a controller (700) configured to control a power factor correction circuit (7) including a DC/DC converter includes a configuration (first configuration) that includes:
a first external terminal (MULT) configured to receive a first voltage (Vmult) having a full-wave rectified waveform;
a second external terminal (IS) configured to receive a first detection voltage (Vis) as a negative voltage generated by a current flowing through a sense resistor (Ris) connected to an application terminal of a ground potential in the power factor correction circuit;
an error amplifier circuit (710) configured to amplify an error between a second detection voltage (Vs) corresponding to an output voltage (Vdc) of the DC/DC converter and a reference voltage (Vref1) to generate a second voltage (V2);
an arithmetic circuit (733) configured to generate a third voltage (V4) by multiplying the first voltage by the second voltage;
an inverting amplifier (734) configured to invert and amplify the first detection voltage to generate a fourth voltage (V5);
a comparator (735) configured to compare the third voltage and the fourth voltage; and
a drive circuit (DRV) configured to drive a switching element in the power factor correction circuit to be turned on or off such that the switching element is turned off each time the fourth voltage becomes higher than the third voltage according to an output of the comparator.

The controller of the first configuration may include a configuration (second configuration) that further includes: an adjuster (733B) configured to be capable of adjusting an offset difference, which is a difference between the third voltage obtained when the first voltage is 0V and the fourth voltage obtained when the first detection voltage is 0 V.

The controller of the second configuration may include a configuration (third configuration) wherein the arithmetic circuit (733) includes:
an arithmetic processor (733A) configured to receive the first voltage and the second voltage and output an output current (Iout);
an offset generator (733B), as an adjuster, configured to variably generate an offset current (Ioffset); and
a resistor (733C) configured such that a current obtained by combining the output current and the offset current flows through the resistor.

The controller of the third configuration may include a configuration (fourth configuration) wherein the offset generator (733B) includes: a first current mirror (CM1); a second current mirror (CM2); a third current mirror (CM3); a first selector (F1) configured to select whether the first current mirror is enabled or disabled; and a second selector (F3) configured to select whether the third current mirror is enabled or disabled, and wherein currents output from the first current mirror, the second current mirror, and the third current mirror are combined to form the offset current.

The controller of the fourth configuration may include a configuration (fifth configuration) wherein each of the first selector and the second selector is a fuse (F1, F3), and whether the first current mirror and the third current mirror are enabled or disabled is selected depending on whether the fuse is cut or not.

The controller of the fifth configuration may include a configuration (sixth configuration) wherein the first current mirror, the second current mirror, and the third current mirror all include a PMOS transistor on an input side and a PMOS transistor on an output side,
wherein the first current mirror includes a first PMOS transistor (PM1) whose source is connected to a drain of the PMOS transistor on the output side, the fuse (F1) connected to a high potential side of a gate of the first PMOS transistor, and a pull-down resistor (Rp1) connected to a low potential side of the gate of the first PMOS transistor, and
wherein the third current mirror includes the fuse (F3) connected to the drain of the

PMOS transistor on the output side.

The controller of any one of the third to sixth configurations may include a configuration (seventh configuration) that further includes: a chip configured to integrate circuits, wherein the chip includes:
the arithmetic processor (733A);
the offset generator (733B);
the inverting amplifier (734);
the comparator (735);
a first pad (P2) configured such that the first voltage is applied to the first pad;
a second pad (P3) configured such that the first detection voltage is applied to the second pad; and
a test pad (P4) connected to an output terminal of the arithmetic processor, an output terminal of the offset generator, and an input terminal of the comparator.

According to one aspect of the present disclosure, a power factor correction circuit (7) includes a configuration (eighth configuration) that includes: the controller of any one of the first to seventh configurations.

According to one aspect of the present disclosure, an electronic device (1) includes a configuration (ninth configuration) that includes:
a rectifier circuit (5) configured to full-wave rectify an AC voltage (Vac); and
the power factor correction circuit (7) of the eighth configuration, which is configured to receive an output voltage (Vh) of the rectifier circuit.

According to one aspect of the present disclosure, an offset setting method performed in a process of manufacturing the controller of the seventh configuration includes a configuration (tenth configuration) that includes:
sweeping a test voltage (Vtest) applied to the test pad with a voltage of 0 V applied to the second pad and measuring the test voltage when an output level of the comparator switches;
measuring a voltage of the test pad with a voltage of 0 V applied to the first pad; and
adjusting the offset difference by using the adjuster based on results of the measuring the test voltage and the measuring the voltage of the test pad.

### INDUSTRIAL APPLICABILITY

The present disclosure can be used in AC/DC converters for various applications.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A controller configured to control a power factor correction circuit including a DC/DC converter, the controller comprising:
a first external terminal configured to receive a first voltage having a full-wave rectified waveform;
a second external terminal configured to receive a first detection voltage as a negative voltage generated by a current flowing through a sense resistor connected to an application terminal of a ground potential in the power factor correction circuit;
an error amplifier circuit configured to amplify an error between a second detection voltage corresponding to an output voltage of the DC/DC converter and a reference voltage to generate a second voltage;
an arithmetic circuit configured to generate a third voltage by multiplying the first voltage by the second voltage;
an inverting amplifier configured to invert and amplify the first detection voltage to generate a fourth voltage;
a comparator configured to compare the third voltage and the fourth voltage; and
a drive circuit configured to drive a switching element in the power factor correction circuit to be turned on or off such that the switching element is turned off each time the fourth voltage becomes higher than the third voltage according to an output of the comparator.

2. The controller of claim 1, further comprising an adjuster configured to be capable of adjusting an offset difference, which is a difference between the third voltage obtained when the first voltage is 0V and the fourth voltage obtained when the first detection voltage is 0 V.

3. The controller of claim 2, wherein the arithmetic circuit includes:
an arithmetic processor configured to receive the first voltage and the second voltage and output an output current;
an offset generator, as the adjuster, configured to variably generate an offset current; and
a resistor configured such that a current obtained by combining the output current and the offset current flows through the resistor.

4. The controller of claim 3, wherein the offset generator includes:
a first current mirror;
a second current mirror;
a third current mirror;
a first selector configured to select whether the first current mirror is enabled or disabled; and
a second selector configured to select whether the third current mirror is enabled or disabled,
wherein currents output from the first current mirror, the second current mirror, and the third current mirror are combined to form the offset current.

5. The controller of claim 4, wherein each of the first selector and the second selector is a fuse, and whether the first current mirror and the third current mirror are enabled or disabled is selected depending on whether the fuse is cut or not.

6. The controller of claim 5, wherein the first current mirror, the second current mirror, and the third current mirror all include a PMOS transistor on an input side and a PMOS transistor on an output side,
wherein the first current mirror includes a first PMOS transistor whose source is connected to a drain of the PMOS transistor on the output side, the fuse connected to a high potential side of a gate of the first PMOS transistor, and a pull-down resistor connected to a low potential side of the gate of the first PMOS transistor, and
wherein the third current mirror includes the fuse connected to the drain of the PMOS transistor on the output side.

7. The controller of claim 3, further comprising a chip configured to integrate circuits, wherein the chip includes:
the arithmetic processor;
the offset generator;
the inverting amplifier;
the comparator;
a first pad configured such that the first voltage is applied to the first pad;
a second pad configured such that the first detection voltage is applied to the second pad; and
a test pad connected to an output terminal of the arithmetic processor, an output terminal of the offset generator, and an input terminal of the comparator.

8. A power factor correction circuit comprising: the controller of claim 1.

9. An electronic device comprising:
a rectifier circuit configured to full-wave rectify an AC voltage; and
the power factor correction circuit of claim 8, which is configured to receive an output voltage of the rectifier circuit.

10. An offset setting method performed in a process of manufacturing the controller of claim 7, comprising:
sweeping a test voltage applied to the test pad with a voltage of 0 V applied to the second pad and measuring the test voltage when an output level of the comparator switches;
measuring a voltage of the test pad with a voltage of 0 V applied to the first pad; and
adjusting the offset difference by using the adjuster based on results of the measuring the test voltage and the measuring the voltage of the test pad.
